(19) United States
(12) Patent Application Publication
(10) Pub. No.: US 2026/0087228 A1
(43) Pub. Date: Mar. 26, 2026

(54) INFORMATION PROCESSING METHOD, COMPUTER PROGRAM, AND INFORMATION PROCESSING APPARATUS

(71) Applicant: Tokyo Electron Limited, Tokyo (JP)

(72) Inventors: Takahiro NAKAMURA, Sapporo City, Hokkaido (JP); Daiki KAWAHITO, Sapporo City, Hokkaido (JP); Pingshan LUAN, Albany, NY (US)

(73) Assignee: Tokyo Electron Limited, Tokyo (JP)

(21) Appl. No.: 19/330,891

(22) Filed: Sep. 17, 2025

(30) Foreign Application Priority Data
Sep. 24, 2024 (JP) 2024-165464

(51) Int. Cl. G06F 30/398; G05B 13/04

(52) U.S. Cl. CPC G06F 30/398; G05B 13/042

(57) ABSTRACT

An information processing method includes: acquiring, based on a result of an experiment obtained by measuring a state of gas or plasma in a substrate processing apparatus that processes a substrate using the gas or plasma, an experimental value of a density of reactive species contained in the gas or plasma during substrate processing; performing a simulation of the state of the gas or plasma during the substrate processing using a reaction coefficient of a reaction between the reactive species contained in the gas or plasma; calculating an estimated value of the density of the reactive species contained in the gas or plasma during the substrate processing based on a result of the simulation; and adjusting the reaction coefficient according to an error between the experimental value and the estimated value.

### CROSS-REFERENCE TO RELATED APPLICATION

This application claims the benefit of priority under 35 U.S.C. § 119(a) from Japanese Patent Application No. 2024-165464, filed on Sep. 24, 2024, the entire contents of which are incorporated herein by reference.

### TECHNICAL FIELD

The present disclosure relates to an information processing method, a computer program, and an information processing apparatus.

### BACKGROUND

Simulations have been performed using a computer with respect to substrate processing in which processing such as etching or film formation is performed on a substrate such as a semiconductor wafer or a glass substrate. For example, process conditions for obtaining a specific substrate can be searched for by adjusting the process conditions of the substrate processing such that a shape of the substrate obtained by the simulations becomes a specific shape. PTL 1 discloses an example of a technique for performing simulations of substrate processing.

### CITATION LIST

### Patent Documents

PTL 1: JP6899659B

### SUMMARY

The substrate processing includes processing using gas or plasma, such as CVD (chemical vapor deposition) or plasma etching. Simulations are also performed with respect to the substrate processing using gas or plasma. When a simulation of the substrate processing using gas or plasma is performed, a reaction coefficient related to reactions among a large number of reactive species such as atoms or ions contained in the gas or plasma is used. In order to improve the accuracy of the simulation, it is necessary to set the reaction coefficient used in the simulation to be accurate.

The disclosure provides an information processing method, a computer program, and an information processing apparatus capable of determining a reaction coefficient.

An information processing method according to an aspect of the disclosure includes: acquiring, based on a result of an experiment obtained by measuring a state of gas or plasma in a substrate processing apparatus that processes a substrate using the gas or plasma, an experimental value of a density of reactive species contained in the gas or plasma during substrate processing; performing a simulation of the state of the gas or plasma during the substrate processing using a reaction coefficient of a reaction between the reactive species contained in the gas or plasma; calculating an estimated value of the density of the reactive species contained in the gas or plasma during the substrate processing based on a result of the simulation; and adjusting the reaction coefficient according to an error between the experimental value and the estimated value.

According to the disclosure, an information processing method, a computer program, and an information processing apparatus capable of determining a reaction coefficient can be provided.

### BRIEF DESCRIPTION OF DRAWINGS

FIG. 1 is a conceptual diagram illustrating a configuration example of an information processing system.

FIG. 2 is a block diagram illustrating an internal configuration example of an information processing apparatus.

FIG. 3 is a table illustrating an example of a plurality of types of reactive species.

FIG. 4 is a table illustrating an example of a plurality of types of electron impact reactions.

FIG. 5 is a table illustrating an example of a plurality of types of heavy particle reactions.

FIG. 6 is a table illustrating a content example of experimental value data.

FIG. 7 is a flowchart illustrating an example of a procedure of processing of determining a reaction coefficient, which is executed by the information processing apparatus.

FIG. 8 is a flowchart illustrating an example of a procedure of processing of controlling a substrate processing apparatus by adjusting process conditions, which is executed by the information processing system.

FIG. 9 is a flowchart illustrating an example of a procedure of processing of analyzing substrate processing, which is executed by the information processing apparatus.

### DETAILED DESCRIPTION

Hereinafter, the disclosure will be specifically described with reference to the drawings illustrating embodiments thereof.

A process for producing a substrate such as a semiconductor wafer, a glass substrate, or a flat panel display substrate includes a process of executing processing such as etching or film formation on a substrate. Hereinafter, the processing performed on the substrate will be referred to as substrate processing, and an apparatus for executing the substrate processing will be referred to as a processing apparatus. For example, the processing apparatus includes a process chamber, and performs the substrate processing, such as etching, on a substrate disposed in the process chamber. The substrate processing includes processing using gas and/or plasma, such as CVD or plasma etching. For example, predetermined gas is introduced into the inside of the process chamber, the gas is formed into plasma by application of a radio frequency voltage, and a surface of the substrate disposed in the process chamber reacts with the gas or plasma, so that the surface of the substrate is etched.

The simulation of the substrate processing may be performed to predict a result of the substrate processing. A plurality of types of reactive species such as atoms, molecules, electrons, excited species, or ions are contained in the gas and plasma during substrate processing. These reactive species react with each other and with the surface of the substrate. When the simulation of the substrate processing using the gas and the plasma is performed, the simulation of the state of the gas and the plasma during the substrate processing is performed. In the simulation of the state of the gas and the plasma, a history of the reaction between the reactive species contained in the gas and the plasma is calculated, and in this calculation, a reaction coefficient such as an impact cross-sectional area is used. The reaction coefficient is a coefficient included in a formula defining the reaction, and is, for example, a coefficient included in a formula expressing a reaction rate. The reaction coefficient exists according to the type of reaction.

In order to perform a simulation with high accuracy, it is necessary to determine the reaction coefficient with high accuracy. In the related art, as a value of the reaction coefficient, a manually set value or a value described in the literature is used. The gas and the plasma contain the plurality of types of reactive species, and a plurality of types of reactions occur. Therefore, a number of reaction coefficients required in the simulation is enormous. Some of the reaction coefficients do not have values described in the literature. Therefore, it is difficult to appropriately manually set the enormous numbers of values of the reaction coefficients. Therefore, a technique for determining the reaction coefficient with high accuracy is desired.

In the embodiment, processing of determining a more appropriate reaction coefficient is performed.

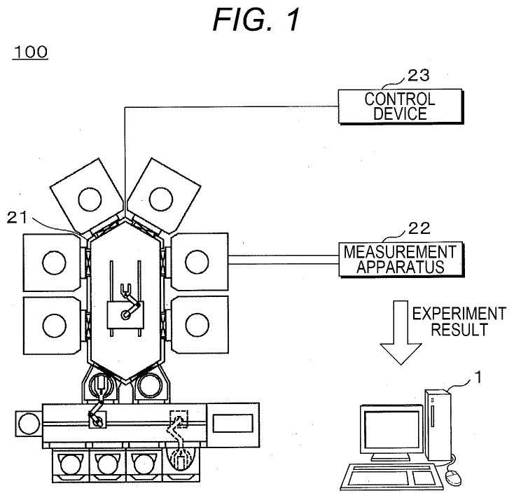

FIG. 1 is a conceptual diagram illustrating a configuration example of an information processing system 100. The information processing system 100 according to the embodiment includes a substrate processing apparatus 21 that executes substrate processing, a measurement apparatus 22 that measures an inner state of the substrate processing apparatus 21, a control device 23 that controls the substrate processing apparatus 21, and an information processing apparatus 1. The substrate processing apparatus 21 performs the substrate processing using gas and plasma on a substrate such as a semiconductor wafer, a glass substrate, or a flat panel display substrate. For example, the substrate processing apparatus 21 includes a process chamber, and performs plasma etching as the substrate processing. The control device 23 controls an operation of the substrate processing apparatus 21. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The measurement apparatus 22 is an apparatus that measures data for determining a composition and a density of the reactive species contained in the gas and the plasma present in the process chamber provided in the substrate processing apparatus 21. The measurement apparatus 22 is connected to the process chamber and measures an inner state of the process chamber. An experiment in which the substrate processing is actually performed using the gas and the plasma in the substrate processing apparatus 21 is performed, and a measurement result of the measurement apparatus 22 is obtained as an experiment result. The measurement apparatus 22 is an optical emission spectrometer (OES), a quadrupole mass spectrometer (QMS), or a Langmuir probe.

The OES is an apparatus for measuring emission spectra from the gas and the plasma, and performing qualitative analysis and quantitative analysis of the reactive species contained in the gas and the plasma based on the emission spectra. The QMS is a type of mass spectrometer, and is an apparatus for measuring a mass of the reactive species contained in the gas and the plasma, and performing the qualitative analysis and the quantitative analysis for the reactive species. The Langmuir probe is an apparatus for measuring characteristics of the plasma such as a potential and a density of the plasma and analyzing a state of the plasma.

The measurement apparatus 22 may be an apparatus other than the OES, the QMS, and the Langmuir probe as long as it is an apparatus that measures data for determining the composition and the density of the reactive species contained in the gas and the plasma. A plurality of types of measurement apparatuses 22 may be connected to the process chamber provided in the substrate processing apparatus 21, and measurements may be performed by the plurality of types of measurement apparatuses 22.

The information processing apparatus 1 executes an information processing method. The information processing apparatus 1 performs processing of searching for a reaction coefficient. More specifically, the information processing apparatus 1 uses the reaction coefficient to perform a simulation of the state of the gas and the plasma present in the process chamber during the substrate processing, and calculates, based on the simulation, an estimated value of a density of the reactive species contained in the gas and the plasma. The information processing apparatus 1 compares an experimental value of the density of the reactive species obtained by measurement of the measurement apparatus 22 with the estimated value, and performs processing of adjusting the reaction coefficient according to a comparison result.

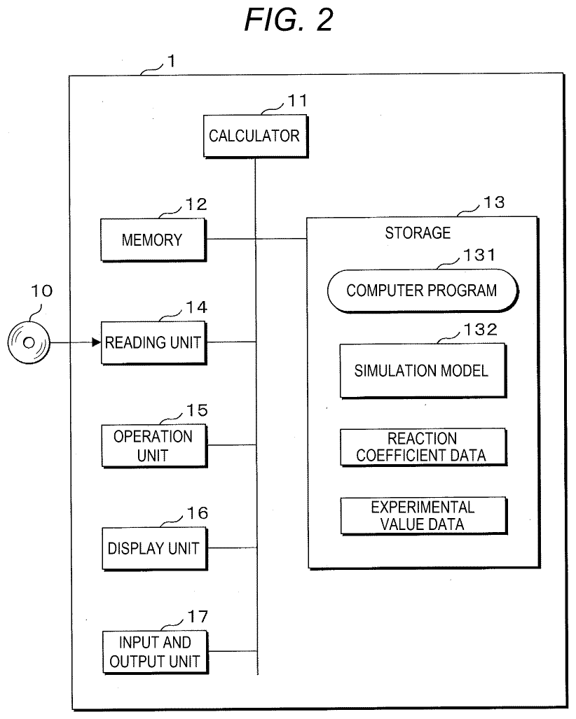

FIG. 2 is a block diagram illustrating an internal configuration example of the information processing apparatus 1. The information processing apparatus 1 is implemented using a computer such as a personal computer or a server apparatus. The information processing apparatus 1 includes a calculator 11, a memory 12, a storage 13, a reading unit 14, an operation unit 15, a display unit 16, and an input and output unit 17. The calculator 11 is a processor, and is implemented using, for example, a central processing unit (CPU), a graphics processing unit (GPU), or a multi-core CPU. The calculator 11 may also be implemented using a quantum computer. The memory 12 stores temporary data generated along with calculation. The memory 12 is, for example, a random access memory (RAM). The storage 13 is non-volatile, and is, for example, a hard disk or a non-volatile semiconductor memory. The reading unit 14 reads information from a recording medium 10 such as an optical disk or a portable memory.

The operation unit 15 receives an input of information such as text by receiving an operation from a user. The operation unit 15 is, for example, a keyboard, a pointing device, or a touch panel. The display unit 16 displays an image. The display unit 16 is, for example, a liquid crystal display or an electroluminescent display (EL display). The operation unit 15 and the display unit 16 may be integrated. The input and output unit 17 inputs and outputs data. The input and output unit 17 is, for example, an input and output interface or a communication unit.

The calculator 11 causes the reading unit 14 to read a computer program (program product) 131 recorded in the recording medium 10, and causes the storage 13 to store the read computer program 131. The calculator 11 executes processing for implementing functions of the information processing apparatus 1 according to the computer program 131. The computer program 131 may be stored in advance in the storage 13 or may be downloaded from outside the information processing apparatus 1.

In this case, the information processing apparatus 1 does not need to be provided with the reading unit 14.

The computer program 131 may be loaded to be executed on a single computer or on a plurality of computers disposed at one site or distributed across a plurality of sites and interconnected by a communication network. That is, the information processing apparatus 1 may be implemented by a plurality of computers, and the computer program 131 may be executed on the plurality of computers connected via the communication network.

The information processing apparatus 1 may be implemented using a cloud server.

Processing of each step to be described later for executing the information processing method can be executed by a plurality of computers. The processing of each step may be executed by different computers. Data used in the processing may be stored in the plurality of computers. The processing of each step can also be executed using a virtual machine. The processing of each step may be executed by a plurality of calculators. The processing of each step may be executed by different calculators. For example, a part of the processing may be executed by one computer, and the other part of the processing may be executed by another computer.

The information processing apparatus 1 includes a simulation model 132 that simulates the state of the gas and the plasma during the substrate processing in the substrate processing apparatus 21. The simulation model 132 simulates the state of the gas and the plasma inside the process chamber based on information related to the process chamber of the substrate processing apparatus 21, information related to process conditions of the substrate processing, and the reaction coefficient. In the simulation, the composition, density, and the like of the gas and the plasma are calculated. The simulation model 132 includes a computer program for the simulation. The computer program for the simulation is stored in the storage 13 and included in, for example, the computer program 131.

The storage 13 stores reaction coefficient data in which a value of the reaction coefficient is recorded. The reaction coefficient data records the reaction coefficient related to the reaction between the reactive species contained in the gas and the plasma present in the process chamber during the substrate processing in the substrate processing apparatus 21. The gas and the plasma in the process chamber may contain a plurality of types of reactive species during the substrate processing.

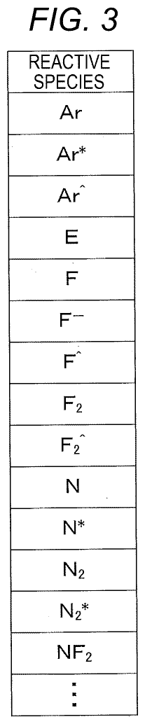

FIG. 3 is a table illustrating an example of a plurality of types of reactive species. The plurality of types of reactive species include various atoms such as Ar (argon), F (fluorine), N (nitrogen), and the like, and various molecules such as F₂ and N₂, and may include electrons denoted by E. “*” in the right shoulder of the symbol of an atom or a molecule represents excited species in which the atom or the molecule is excited. For example, Ar* represents argon-excited species. The plurality of types of reactive species may include various excited species. “\hat{ }” in the right shoulder of the symbol of an atom or a molecule represents a positive ion, and “−” represents a negative ion. For example, F represents a positive ion of fluorine, and the F⁻ represents a negative ion of fluorine. The plurality of types of reactive species may include various excited species. The reactive species illustrated in FIG. 3 are examples, and the gas and the plasma may contain other reactive species. The gas and the plasma may contain atoms, molecules, or ions that have become unstable. Any of the reactive species illustrated in FIG. 3 may not be included in the gas and the plasma.

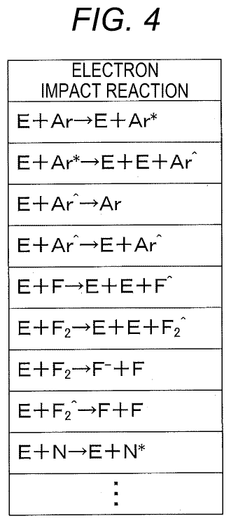

During the substrate processing, an electron impact reaction in which electrons impact other reactive species occurs in the gas and the plasma. A plurality of types of electron impact reactions may occur in which the types of reactive species that impact electrons or the types of reactive species that are generated as a result of the reactions are different. FIG. 4 is a table illustrating an example of a plurality of types of electron impact reactions. FIG. 4 illustrates the plurality of types of electron impact reactions, such as a reaction in which electrons and atoms or molecules impact each other to generate electrons and excited species, a reaction in which electrons and positive ions impact each other to generate atoms or molecules, a reaction in which the reactive species do not change even when impact with electrons, and a reaction in which electrons and molecules impact each other to generate negative ions and atoms. As illustrated in FIG. 4, many types of electron impact reactions may occur. The example of the electron impact reaction illustrated in FIG. 4 is an example, and other electron impact reactions may be assumed. Any of the electron impact reactions illustrated in FIG. 4 may not be assumed.

A reaction rate kₑ of the electron impact reaction can be represented by Formula (1) below, where ε is electron energy, f(ε) is a velocity distribution function of electrons, and v is a velocity of reactive species.

kₑ=∫f(ε)·v·σ(ε)·dε (1)

σ(ε) included in Formula (1) is an impact cross-sectional area and is one of reaction coefficients. The reaction coefficient data records a value of σ(ε), which is the reaction coefficient, for each of the plurality of types of electron impact reactions.

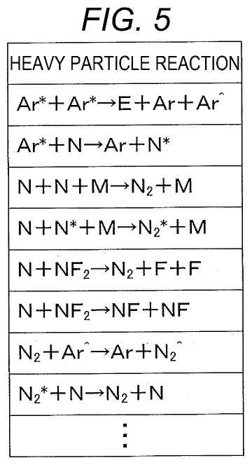

During the substrate processing, in addition to the electron impact reactions, a heavy particle reaction in which reactive species other than electrons impact each other occurs in the gas and the plasma. A plurality of types of heavy particle reactions may occur in which the types of reactive species that impact each other or the types of reactive species that are generated as a result of the reactions are different. FIG. 5 is a table illustrating an example of a plurality of types of heavy particle reactions. M illustrated in FIG. 5 represents a third entity that does not directly participate in the reaction. FIG. 5 illustrates the plurality of types of heavy particle reactions, such as a reaction in which excited species impact each other to generate electrons, atoms, and positive ions, a reaction in which excited species and atoms or molecules impact each other and the excited atoms or molecules replace with each other, a reaction in which atoms or molecules and ions impact each other to transfer charges, a reaction in which atoms and atoms impact each other to generate molecules, and a reaction in which molecules are decomposed. As illustrated in FIG. 5, many types of heavy particle reactions may occur. The example of the heavy particle reaction illustrated in FIG. 5 is an example, and other heavy particle reactions may be assumed. Any of the heavy particle reactions illustrated in FIG. 5 may not be assumed.

Under the assumption of the Maxwell distribution, a reaction rate k of the heavy particle reaction can be represented by Formula (2) below, where T is a temperature, and R is a gas constant.

k=A·Tⁿ·exp(−E_{act}/RT) (2)

A included in Formula (2) is a frequency factor, n is an index, and E_{act} is activation energy, all of which are reaction coefficients. The reaction coefficient data records values of A, n, and E_{act}, which are the reaction coefficients, for each of the plurality of types of heavy particle reactions.

Formula (1) and Formula (2) are examples of formulas defining reactions between reactive species. Other formulas established under different assumptions or models may be used as the formulas defining the reactions, and coefficients different from the coefficients included in Formula (1) and Formula (2) may be used as the reaction coefficients.

In a stage before the information processing apparatus 1 performs processing for determining the reaction coefficients, any initial value is recorded as the value of the reaction coefficient in the reaction coefficient data. The initial value is, for example, a specific constant or a value described in the literature.

The storage 13 stores experimental value data in which an experimental value of the density of the reactive species contained in the gas or the plasma during the substrate processing is recorded. The substrate processing for processing the substrate is actually performed using the gas and the plasma in the substrate processing apparatus 21, and an experiment is performed in which the measurement apparatus 22 measures the state of the gas and the plasma during the substrate processing. Based on the experiment result, the densities of the plurality of types of reactive species contained in the gas and the plasma during the substrate processing are calculated. A value of the density of the reactive species calculated based on the experiment result is the experimental value of the density of the reactive species. As described above, the measurement apparatus 22 is an OES, QMS, or Langmuir probe, and the densities of the plurality of types of reactive species contained in the gas and the plasma during the substrate processing are calculated as experimental values based on the measurement result of the measurement apparatus 22.

For example, the density of each reactive species contained in the gas and the plasma is calculated based on the emission spectra measured by the OES. For example, each reactive species is specified based on the mass measured by the QMS, and the density of each reactive species is calculated based on a measured amount of each reactive species. For example, the density of each reactive species is calculated based on the characteristics of the plasma measured by the Langmuir probe.

The experiments are performed under specific experimental conditions. The experimental conditions include the process conditions for the substrate processing. The process conditions include the composition of the gas introduced into the process chamber, a flow rate of each gas component, a temperature, a pressure, a voltage, a frequency of the voltage, and the like. The experimental conditions may include conditions related to the process chamber such as a shape of the process chamber, or information related to the substrate such as a shape of the substrate. In the experiment, the substrate processing apparatus 21 performs the substrate processing a plurality of times under different conditions such as the process conditions, and the measurement apparatus 22 measures the state of the gas and the plasma for each substrate processing. The density of each reactive species contained in the gas and the plasma is calculated for each substrate processing. That is, a plurality of experiments are performed under a plurality of experimental conditions, and the experimental value of the density of each reactive species is calculated for each experiment. The experimental values obtained for the plurality of experiments are recorded in the experimental value data.

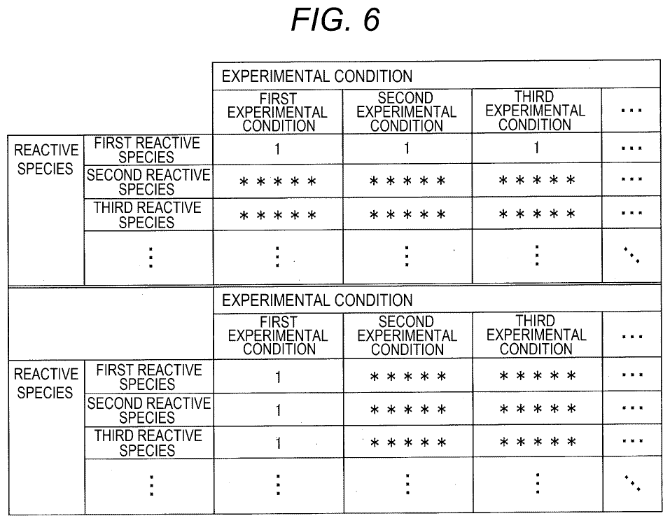

FIG. 6 is a table illustrating a content example of experimental value data. In the experimental value data, a value obtained by normalizing the density of the reactive species is recorded as the experimental value. In FIG. 6, [*****] represents an experimental value. Two types of experimental values normalized by two different methods are recorded in the experimental value data. As a first type of the experimental value, a value normalized by dividing the densities of the plurality of types of reactive species by a density of one specific type of reactive species is recorded. The one specific type of reactive species is referred to as a first reactive species. In the experimental value data, experimental values are recorded in association with the respective reactive species. Since the density of the first reactive species is normalized, the experimental value associated with the first reactive species is 1. Experimental values normalized by dividing densities of other reactive species such as a second reactive species and a third reactive species by the density of the first reactive species are recorded in association with the respective reactive species. The experimental values of the densities of the plurality of types of reactive species are recorded for the plurality of experimental conditions.

In the experimental value data, a value normalized by dividing the densities of the reactive species obtained based on the results of the plurality of experiments performed under the plurality of experimental conditions by a density of reactive species obtained based on a result of an experiment performed under one specific experimental condition is recorded as a second type of the experimental value. The one specific experimental condition is defined as a first experimental condition. In the experimental value data, experimental values are recorded in association with the respective experimental conditions. Since the density of the reactive species is normalized based on the result of the experiment under the first experimental condition, the experimental value associated with the first experimental condition is 1. Experimental values normalized by dividing densities of the reactive species obtained under other experimental conditions such as a second experimental condition and a third experimental condition by the density of the reactive species obtained under the first experimental condition are recorded in association with the respective experimental conditions. The experimental values obtained under the plurality of experimental conditions are recorded for the plurality of reactive species.

The information processing apparatus 1 receives the measurement results from the measurement apparatus 22 through the input and output unit 17, calculates the densities of the reactive species based on the measurement results, and calculates the experimental values of the densities of the respective reactive species by performing normalization. The information processing apparatus 1 stores, in the storage 13, the experimental value data recording the calculated experimental values. The processing of calculating the experimental values of the densities of the respective reactive species based on the measurement results may be performed by an information processing apparatus other than the information processing apparatus 1. In this case, the information processing apparatus 1 receives, through the input and output unit 17, experimental values calculated by another information processing apparatus, and stores, in the storage 13, the experimental value data recording the experimental values.

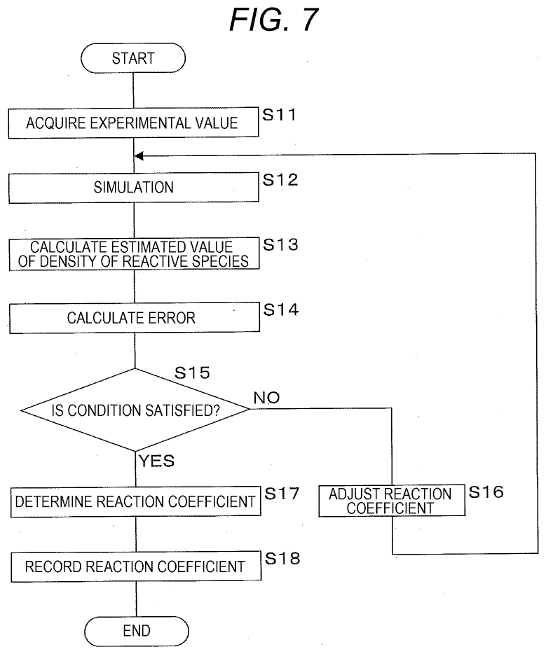

Next, information processing executed by the information processing apparatus 1 will be described. FIG. 7 is a flowchart illustrating an example of a procedure of processing of determining the reaction coefficient, which is executed by the information processing apparatus 1. Hereinafter, step will be abbreviated as S. The information processing apparatus 1 executes the following processing by the calculator 11 executing the information processing according to the computer program 131.

The substrate processing apparatus 21 and the measurement apparatus 22 perform experiments, and the experimental values of the densities of the reactive species contained in the gas and the plasma during the substrate processing are recorded in the experimental value data stored in the storage 13 of the information processing apparatus 1. The information processing apparatus 1 acquires the experimental values of the densities of the plurality of types of reactive species (S11). In S11, the calculator 11 acquires the experimental values by reading the experimental values of the densities of the plurality of types of reactive species from the experimental value data stored in the storage 13. In S11, the calculator 11 may acquire the experimental values by receiving the measurement results from the measurement apparatus 22 and calculating the experimental values of the densities of the plurality of types of reactive species based on the measurement results. In step S11, the calculator 11 may acquire experimental values by receiving experimental values calculated by another information processing apparatus, and storing in the storage 13 the experimental value data in which the received experimental values are recorded.

In step S12, the information processing apparatus 1 then performs a simulation of the state of the gas and the plasma during the substrate processing. In step S12, the calculator 11 uses the simulation model 132 to perform the simulation of the state of the gas and the plasma present in the process chamber during the substrate processing. At this time, the calculator 11 performs a simulation using values of various reaction coefficients recorded in the reaction coefficient data. The calculator 11 performs the simulation of the state of the gas and the plasma during the substrate processing performed under the same experimental condition as those in the experiment performed by the substrate processing apparatus 21.

For example, the simulation model 132 includes a global model, a fluid model, and a particle model. The global model is a model that approximates the inside of the process chamber in a zero-dimensional space, and calculates temporal changes in a composition, a density, and a temperature of the plasma. The fluid model is a model that approximates the inside of the process chamber as a fluid divided by a large number of spatial meshes, and calculates spatial distributions and temporal changes in the composition, the density, and the temperature of the plasma. The particle model describes a behavior of each particle in the process chamber, and is a model for calculating the spatial distributions and the temporal changes in the composition, the density, and the temperature of the plasma. The calculator 11 inputs information necessary for simulations, such as experimental conditions and reaction coefficients, into the simulation model 132, and performs the simulation of the state of the gas and the plasma using the simulation model 132. The calculator 11 performs the simulation of the state of the gas and the plasma for each of the plurality of experimental conditions.

The information processing apparatus 1 calculates, based on a result of the simulation, an estimated value of the density of the reactive species (S13). The estimated value is a value of the density of reactive species calculated based on the result of the simulation. In step S13, the calculator 11 calculates estimated values of the densities of the plurality of types of reactive species contained in the gas and the plasma during the substrate processing, based on the results of the simulations of the state of the gas and the plasma during the substrate processing. For example, the calculator 11 calculates an estimated value of the density of each reactive species at the same timing as the timing at which the measurement apparatus 22 performs a measurement in an experiment.

In S13, the calculator 11 calculates two types of estimated values normalized by two different methods. The calculator 11 calculates, as a first type of the estimated value, a value normalized by dividing the densities of the plurality of types of reactive species by the density of the first reactive species. The calculator 11 calculates the first type of the estimated value of the plurality of types of reactive species for each of the plurality of experimental conditions. The calculator 11 calculates, as a second type of the estimated value, a value normalized by dividing the density of the reactive species calculated using the plurality of experimental conditions by the density of the reactive species calculated using the first experimental condition. The calculator 11 calculates the second type of the estimated value calculated using the plurality of experimental conditions for each of the plurality of reactive species. The calculator 11 stores the calculated estimated value in the memory 12 or the storage 13.

The information processing apparatus 1 then calculates an error between the experimental value and the estimated value (S14). In step S14, the calculator 11 calculates the error between the experimental value acquired in step S11 and the estimated value calculated in step S13. For example, the calculator 11 calculates the error using a predetermined error function. The error function is included in the computer program 131. For example, the calculator 11 calculates a mean square error as the error. At this time, the calculator 11 calculates a difference between the first type of the experimental value and the first type of the estimated value related to the same reactive species and the same experimental condition, and adds the square of the difference across all the reactive species and all the experimental conditions. At this time, the calculator 11 calculates a difference between the second type of the experimental value and the second type of the estimated value related to the same reactive species and the same experimental condition, and adds the square of the difference across all the reactive species and all the experimental conditions. The calculator 11 calculates a mean square error by adding a sum of the squares of the two types of differences.

Next, the information processing apparatus 1 determines whether a specific condition is satisfied (S15). In step S15, the calculator 11 determines whether a condition that the error calculated in step S14 falls within a predetermined range is satisfied. For example, the calculator 11 determines whether a condition that a value of the error is less than a predetermined threshold value is satisfied. The specific condition may be a condition that an amount of change in the error updated by being repeatedly calculated in S14 is less than a predetermined lower limit value. The specific condition may be a condition that the number of repetitions of the processing of S12 to S16 or a calculation time reaches a predetermined upper limit.

When the specific condition is not satisfied (S15: NO), the information processing apparatus 1 adjusts various reaction coefficients (S16). In step S16, the user may operate the operation unit 15 to input a correction content of the reaction coefficients, and the calculator 11 may adjust the reaction coefficients according to the received correction content. The calculator 11 may adjust the reaction coefficients without using an input from the user. In step S16, the calculator 11 may adjust the reaction coefficients such that the error between the experimental value and the estimated value of the density of the reactive species becomes small. For example, the calculator 11 stores, in the storage 13, a history of the correction of the reaction coefficients and the change of the error, and corrects the reaction coefficients based on the stored history such that the error becomes small. For example, the calculator 11 may adjust the reaction coefficients through Bayesian optimization. The calculator 11 records the adjusted reaction coefficients in the reaction coefficient data.

After step S16 is completed, the information processing apparatus 1 returns the processing to step S12. In step S12, the information processing apparatus 1 uses the adjusted reaction coefficients to perform a simulation of the state of the gas and the plasma. The information processing apparatus 1 repeats the processing of S12 to S16 until the specific condition is satisfied. By repeating the processing of S12 to S16, the information processing apparatus 1 adjusts the various reaction coefficients such that the experimental value and the estimated value of the density of the reactive species substantially coincide with each other. When the experimental value and the estimated value of the density of the reactive species substantially coincide with each other, values of the adjusted reaction coefficients may be estimated to be close to values of actual reaction coefficients.

When the specific condition is satisfied (S15: YES), the information processing apparatus 1 determines various reaction coefficients (S17). In step S17, the calculator 11 determines that the reaction coefficients used in the simulation are actual reaction coefficients. The reaction coefficients are repeatedly adjusted by the processing of S12 to S16, and may be estimated to be close to the actual reaction coefficients. Therefore, the information processing apparatus 1 can determine the adjusted reaction coefficients as the actual reaction coefficients. The information processing apparatus 1 records the determined reaction coefficients (S18). In step S18, the calculator 11 records the determined reaction coefficients in the reaction coefficient data stored in the storage 13. After step S18 is completed, the information processing apparatus 1 ends the processing of determining the reaction coefficients.

As described above, the information processing apparatus 1 performs the simulation of the state of the gas and the plasma using the reaction coefficient of the reactive species, compares a simulation result and an experiment result, and adjusts the reaction coefficient according to the comparison result. The result of the simulation using the reaction coefficient deviate from the experiment result when the value of the reaction coefficient is not appropriate, and approach the experiment result when the value of the reaction coefficient is appropriate. The reaction coefficient is adjusted such that the simulation result is close to the experiment result, and specifically, the error between the experimental value and the estimated value of the density of the reactive species is small, so that the reaction coefficient becomes an appropriate value. Accordingly, the information processing apparatus 1 can accurately specify reaction coefficients of reactions among the plurality of types of reactive species contained in the gas and the plasma during the substrate processing.

Since the reaction coefficients can be specified without manually setting the reaction coefficients, it is not necessary to manually set enormous values of the reaction coefficients, and the labor required for simulations is reduced. According to the embodiment, it is also possible to specify values with high accuracy for reaction coefficients that do not have values described in the literature.

In the embodiment, the information processing apparatus 1 compares the experimental value and the estimated value of the density of the reactive species, after normalizing the densities of the plurality of types of reactive species included in the gas and the plasma. Since the experimental value and the estimated value are obtained by different methods, it is difficult to compare absolute values. However, it is easier to compare relative values of a plurality of experimental values and relative values of a plurality of estimated values. By normalizing the experimental value and the estimated value of the density of the reactive species, it becomes easy to compare the experimental value and the estimated value, and it becomes possible to perform processing of adjusting the reaction coefficient.

In the embodiment, normalization is performed by two different methods, that is, a method of normalizing the densities of the plurality of types of reactive species by the density of the specific one type of reactive species, and a method of normalizing the densities of the reactive species obtained under the plurality of conditions by the density of the reactive species obtained under the specific one condition. Since two types of the relative values are compared between the experimental value and the estimated value, the experimental value and the estimated value can be compared in detail, and the reaction coefficient can be specified with higher accuracy. The information processing apparatus 1 may be configured to standardize only one of the experimental value and the estimated value.

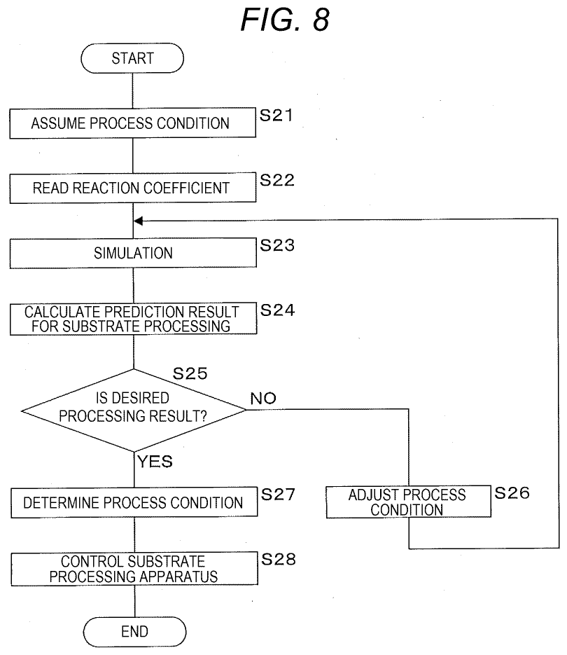

The information processing system 100 can perform processing of adjusting the process conditions of the substrate processing using the determined reaction coefficients. FIG. 8 is a flowchart illustrating an example of a procedure of processing of controlling the substrate processing apparatus 21 by adjusting the process conditions, which is executed by the information processing system 100. The information processing apparatus 1 records the reaction coefficients determined in the processing of S11 to S18 in the reaction coefficient data stored in the storage 13. The reaction coefficient data corresponds to a database. In step S21, the information processing apparatus 1 assumes process conditions of the substrate processing. In step S21, the user operates the operation unit 15 to input a content of the process conditions, and the calculator 11 assumes process conditions according to the received content. The calculator 11 may assume process conditions for a predetermined content.

The information processing apparatus 1 reads, from the reaction coefficient data, reaction coefficients of the reaction between the reactive species contained in the gas and the plasma during the substrate processing (S22). In step S22, the calculator 11 reads the reaction coefficients from the reaction coefficient data stored in the storage 13. The information processing apparatus 1 performs a simulation of the state of the gas and the plasma during the substrate processing (S23). In step S23, the calculator 11 uses the simulation model 132 to perform the simulation of the state of the gas and the plasma present in the process chamber during the substrate processing. At this time, the calculator 11 performs a simulation using the assumed process conditions and the read reaction coefficients. In step S23, the calculator 11 performs a simulation of an interaction between the gas and plasma in the process chamber and the surface of the substrate disposed in the process chamber.

The information processing apparatus 1 calculates a prediction result for the substrate processing based on the result of the simulation (S24). In step S24, the calculator 11 calculates, based on the result of the simulation of the state of the gas and the plasma during the substrate processing, the prediction result that predicts what result will be obtained by the substrate processing using the gas and the plasma. For example, the calculator 11 calculates, as a prediction result, a predicted feature of a shape of the surface of the substrate after the substrate processing.

The information processing apparatus 1 determines whether the calculated prediction result of the substrate processing is a desired processing result (S25). The desired processing result is a desired result of the substrate processing. In step S25, the calculator 11 compares the calculated prediction result of the substrate processing with a predetermined desired processing result, and performs a determination based on the comparison result. For example, the desired processing result is input into the information processing apparatus 1 by the user operating the operation unit 15. For example, the calculator 11 calculates the error between the prediction result of the substrate processing and the desired processing result using the predetermined error function, and when the error is less than a predetermined threshold value, the calculator 11 determines that the prediction result of the substrate processing is the desired processing result. When the error is not less than the predetermined threshold value, the calculator 11 determines that the prediction result of the substrate processing is not the desired processing result.

When the prediction result of the substrate processing is not the desired processing result (S25: NO), the information processing apparatus 1 adjusts the process conditions (S26). In step S26, the user may operate the operation unit 15 to input a correction content of the process conditions, and the calculator 11 may adjust the process conditions according to the received correction content. The calculator 11 may adjust the process conditions without using the input from the user. In step S26, the calculator 11 may adjust the process conditions or may randomly adjust the process conditions such that the error between the prediction result of the substrate processing and the desired processing result becomes small.

After step S26 is completed, the information processing apparatus 1 returns the processing to step S23. In step S23, the information processing apparatus 1 uses the adjusted process conditions to perform a simulation of the state of the gas and the plasma. The information processing apparatus 1 repeats the processing of steps S23 to S26 until the prediction result of the substrate processing becomes the desired processing result. By repeating the processing of steps S23 to S26, the information processing apparatus 1 adjusts the process conditions such that the prediction result of the substrate processing becomes the desired processing result. Accordingly, the process conditions are adjusted so as to obtain the desired processing result.

When the prediction result of the substrate processing is the desired processing result (S25: YES), the information processing apparatus 1 determines the process conditions (S27). In step S27, the calculator 11 determines that the process conditions used in the simulation are process conditions for obtaining the desired processing result. The process conditions are repeatedly adjusted by the processing of steps S23 to S26, and become the process conditions for obtaining the desired processing result. The calculator 11 stores the determined process conditions in the storage 13.

The control device 23 controls the substrate processing apparatus 21 using the determined process conditions (S28). In step S28, the control device 23 acquires the process conditions from the information processing apparatus 1, operates the substrate processing apparatus 21, and controls the substrate processing apparatus 21 so as to execute the substrate processing according to the process conditions. The substrate processing is actually performed according to the determined process conditions, and the desired processing result is actually obtained. After step S28 is completed, the information processing system 100 ends the processing.

The processing in steps S21 to S28 may be executed by another information processing system different from the information processing system 100. For example, the reaction coefficient determined by the information processing apparatus 1 in the processing of S11 to S18 may be input to another information processing apparatus, and the processing of S21 to S28 may be executed by an information processing system including another information processing apparatus to which the reaction coefficient has been input. Another information processing apparatus records the input reaction coefficient in the database, and executes a simulation using the reaction coefficient read from the database. The processing of steps S21 to S27 and the processing of step S28 may be executed at different timings without being consecutively performed. The processing of steps S21 to S27 and the processing of step S28 may be executed by different information processing systems. For example, the process conditions determined by the information processing apparatus 1 in the processing of S21 to S27 may be input to another information processing apparatus, and the processing of S28 may be executed by an information processing system including another information processing apparatus to which the process conditions have been input.

Since the reaction coefficients of the reactions among the plurality of types of reactive species are determined with high accuracy, the simulation using the reaction coefficients can be performed with high accuracy. By using the highly accurate simulation, the processing of adjusting the process conditions can be performed with high accuracy, and appropriate process conditions can be specified with high accuracy. For example, it is possible to accurately specify process conditions necessary for obtaining a substrate having a desired shape by the substrate processing. By actually performing the substrate processing using the specified process conditions, the substrate having the desired shape can be generated.

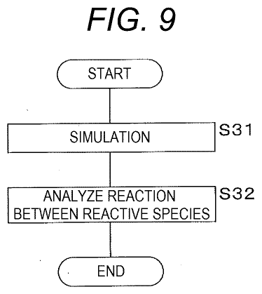

The information processing apparatus 1 can analyze the substrate processing using the determined reaction coefficients. FIG. 9 is a flowchart illustrating an example of a procedure of processing of analyzing the substrate processing, which is executed by the information processing apparatus 1. The information processing apparatus 1 performs a simulation of the state of the gas and the plasma during the substrate processing (S31). In step S31, the calculator 11 uses the simulation model 132 to perform the simulation of the state of the gas and the plasma present in the process chamber during the substrate processing. At this time, the calculator 11 performs a simulation using the reaction coefficients determined in the processing of S11 to S18.

The information processing apparatus 1 analyzes, based on the result of the simulation, the reaction between the reactive species contained in the gas and the plasma during the substrate processing (S32). In step S32, the calculator 11 performs analysis using an existing analysis method. For example, the calculator 11 specifies the history of the reactions among the plurality of reactive species according to the temporal change of the density of each reactive species obtained by the simulation. For example, factors of the reactions among the plurality of reactive species are specified according to states inside the process chamber during the substrate processing obtained by the simulation, such as spatial distributions and temporal changes in a temperature and a pressure, and a spatial distribution or a temporal change in the density of each reactive species.

In step S32, the user may operate the operation unit 15 to input an instruction for analysis, and the calculator 11 may execute analysis according to the input instruction. The processing of steps S31 to S32 may be appropriately repeated. For example, the simulation may be repeated while changing conditions such as process conditions or conditions related to the process chamber, so as to search for the factors of the reactions among the reactive species contained in the gas and the plasma.

After step S32 is completed, the information processing apparatus 1 ends the processing of analyzing the substrate processing. The processing of steps S31 to S32 may be executed by another information processing apparatus different from the information processing apparatus 1. For example, the reaction coefficients determined by the information processing apparatus 1 in the processing of S11 to S18 may be input to another information processing apparatus, and the processing of S31 to S32 may be executed by another information processing apparatus to which the reaction coefficients have been input.

By using a highly accurate simulation, it is possible to appropriately analyze reactions among the reactive species. For example, the states of the reactive species that cannot be obtained by measurements using sensors alone, such as the spatial distributions or the temporal changes of the densities of the reactive species, can be accurately reproduced by simulations, and the history or the factors of the reactions among the reactive species can be specified in more detail than in the related art. An analysis result can be used for improvement or development of the substrate processing apparatus 21 by correcting the configuration or function of the substrate processing apparatus 21 based on the analysis result.

In the embodiment, the reaction coefficients of the reactions among the plurality of types of reactive species contained in the gas and the plasma during the substrate processing have been adjusted. The information processing apparatus 1 may adjust the reaction coefficients of the reactions among the plurality of types of reactive species contained only in the gas during the substrate processing, or may adjust the reaction coefficients of the reactions among the plurality of types of reactive species contained only in the plasma during the substrate processing.

The invention is not limited to contents of the above-described embodiment, and various modifications may be made within the scope described in the following claims. In other words, embodiments obtained by combining technical means appropriately changed within the scope indicated in the claims are also included in the technical scope of the invention.

The features described in each embodiment can be combined with each other. In addition, the independent and dependent claims set forth in the claims can be combined with each other in any and all combinations, regardless of the reciting format. Furthermore, the claims do not use a format of describing claims that recite two or more other claims (multi-claim format). However, the disclosure is not limited thereto. The claims may also be described using a format of multi-claims reciting at least one multi-claim format or multi-claim (multi-multi claims). The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

1. An information processing method comprising:
acquiring, based on a result of an experiment obtained by measuring a state of gas or plasma in a substrate processing apparatus that processes a substrate using the gas or plasma, an experimental value of a density of reactive species contained in the gas or plasma during substrate processing;
performing a simulation of the state of the gas or plasma during the substrate processing using a reaction coefficient of a reaction between the reactive species contained in the gas or plasma;
calculating an estimated value of the density of the reactive species contained in the gas or plasma during the substrate processing based on a result of the simulation; and
adjusting the reaction coefficient according to an error between the experimental value and the estimated value.

2. The information processing method according to claim 1, further comprising:
repeating the performing of the simulation, the calculation of the estimated value, and the adjustment of the reaction coefficient.

3. The information processing method according to claim 1, wherein
the experimental value and the estimated value consist of a value obtained by normalizing densities of a plurality of types of reactive species by a density of any one type of the reactive species, and/or a value obtained by normalizing densities of reactive species, based on results of a plurality of experiments performed under a plurality of experimental conditions, by a density of reactive species based on a result of an experiment performed under any one of the experimental conditions.

4. The information processing method according to claim 1, wherein
the experiment uses an OES, a QMS, or a Langmuir probe.

5. The information processing method according to claim 1, wherein
the simulation is performed using the adjusted reaction coefficient and a process condition of the substrate processing in the substrate processing apparatus, and
the information processing method further comprising:
calculating a prediction result of the substrate processing in the substrate processing apparatus based on the result of the simulation; and
adjusting the process condition based on the prediction result.

6. The information processing method according to claim 5, further comprising:
controlling the substrate processing apparatus using the adjusted process condition.

7. The information processing method according to claim 1, wherein
the simulation is performed using the adjusted reaction coefficient, and
the information processing method further comprises:
specifying, based on the result of the simulation, a history or a factor of the reaction that occurs between the reactive species contained in the gas or plasma during the substrate processing.

8. A non-transitory computer-readable storage medium having computer-executable instructions stored thereon, which when executed by a processor, cause the processor to perform a method comprising:
acquiring, based on a result of an experiment obtained by measuring a state of gas or plasma in a substrate processing apparatus that processes a substrate using the gas or plasma, an experimental value of a density of reactive species contained in the gas or plasma during substrate processing;
performing a simulation of the state of the gas or plasma during the substrate processing using a reaction coefficient of a reaction between the reactive species contained in the gas or plasma;
calculating an estimated value of the density of the reactive species contained in the gas or plasma during the substrate processing based on a result of the simulation; and
adjusting the reaction coefficient according to an error between the experimental value and the estimated value.

9. The non-transitory computer-readable storage medium according to claim 8, wherein
the method further comprises repeating the performing of the simulation, the calculation of the estimated value, and the adjustment of the reaction coefficient.

10. The non-transitory computer-readable storage medium according to claim 8, wherein
the experimental value and the estimated value consist of a value obtained by normalizing densities of a plurality of types of reactive species by a density of any one type of the reactive species, and/or a value obtained by normalizing densities of reactive species, based on results of a plurality of experiments performed under a plurality of experimental conditions, by a density of reactive species based on a result of an experiment performed under any one of the experimental conditions.

11. The non-transitory computer-readable storage medium according to claim 8, wherein
the experiment uses an OES, a QMS, or a Langmuir probe.

12. The non-transitory computer-readable storage medium according to claim 8, wherein
the simulation is performed using the adjusted reaction coefficient and a process condition of the substrate processing in the substrate processing apparatus, and
the method further comprising:
calculating a prediction result of the substrate processing in the substrate processing apparatus based on the result of the simulation; and
adjusting the process condition based on the prediction result.

13. The non-transitory computer-readable storage medium according to claim 12, wherein the method further comprises:
controlling the substrate processing apparatus using the adjusted process condition.

14. The non-transitory computer-readable storage medium according to claim 8, wherein
the simulation is performed using the adjusted reaction coefficient, and
the method further comprises specifying, based on the result of the simulation, a history or a factor of the reaction that occurs between the reactive species contained in the gas or plasma during the substrate processing.

15. An information processing apparatus comprising:
circuitry configured to:
acquire, based on a result of an experiment obtained by measuring a state of gas or plasma in a substrate processing apparatus that processes a substrate using the gas or plasma, an experimental value of a density of reactive species contained in the gas or plasma during substrate processing,
perform a simulation of the state of the gas or plasma during the substrate processing using a reaction coefficient of a reaction between the reactive species contained in the gas or plasma,
calculate an estimated value of the density of the reactive species contained in the gas or plasma during the substrate processing based on a result of the simulation, and
adjust the reaction coefficient according to an error between the experimental value and the estimated value.

16. The information processing apparatus according to claim 15, wherein
the circuitry is configured to repeat the performing of the simulation, the calculation of the estimated value, and the adjustment of the reaction coefficient.

17. The information processing apparatus according to claim 15, wherein
the experimental value and the estimated value consist of a value obtained by normalizing densities of a plurality of types of reactive species by a density of any one type of the reactive species, and/or a value obtained by normalizing densities of reactive species, based on results of a plurality of experiments performed under a plurality of experimental conditions, by a density of reactive species based on a result of an experiment performed under any one of the experimental conditions.

18. The information processing apparatus according to claim 15, wherein
the circuitry is configured to perform the simulation using the adjusted reaction coefficient and a process condition of the substrate processing in the substrate processing apparatus, and
the circuitry is further configured to:
calculate a prediction result of the substrate processing in the substrate processing apparatus based on the result of the simulation; and
adjust the process condition based on the prediction result.

19. The information processing apparatus according to claim 18, wherein the circuitry is further configured to:
control the substrate processing apparatus using the adjusted process condition.

20. The information processing apparatus according to claim 19, wherein
the simulation is performed using the adjusted reaction coefficient, and
the circuitry is further configured to specify, based on the result of the simulation, a history or a factor of the reaction that occurs between the reactive species contained in the gas or plasma during the substrate processing.
